(19) United States
(12) Patent Application Publication
(10) Pub. No.: US 2012/0142132 A1
(43) Pub. Date: Jun. 7, 2012

(54) METHOD OF MANUFACTURING OPTICAL MATRIX DEVICE

(75) Inventor: Susumu Adachi, Hirakata-shi (JP)

(73) Assignee: SHIMADZU CORPORATION, Kyoto-shi, Kyoto (JP)

(21) Appl. No.: 13/389,852

(22) PCT Filed: Aug. 11, 2009
(86) PCT No.: PCT/JP2009/003855

§ 371 Date: Feb. 10, 2012

(51) Int. Cl. H01L 33/08

(52) U.S. Cl. 438/34; 257/E33.012

(57) ABSTRACT

According to a method of manufacturing an optical matrix device of this invention, an extension-promoting pattern that promotes extension of droplets printed and coated is formed on an insulation film as a foundation layer where printing patterns are to be formed, whereby the droplets extend along the extension-promoting pattern. Moreover, an extension-inhibiting pattern is formed at end portions of the printing patterns as to intersect the printing patterns, i.e., the extension-promoting pattern, whereby the extension-inhibiting pattern stops extension of the droplets extending along the extension-promoting pattern. Accordingly, control may be made of positional accuracy of the liquid droplets.

### CROSS REFERENCE TO RELATED APPLICATIONS

This application is a U.S. National Stage application under 35 U.S.C. §371, of International Application PCT/JP20091003855 filed on Aug. 11, 2009, which was published as WO 2011/018820 on Feb. 17, 2011 The application is incorporated herein by reference.

### TECHNICAL FIELD

This invention relates to a method of manufacturing an optical matrix device having a structure of pixels formed of display elements or light receiving elements arranged in a matrix in a two-dimensional array, such as a thin image display device used as a monitor of a television or a personal computer, or a radiation detector provided in radiographic apparatus used in the medical field, industrial field, or the like.

### BACKGROUND

An optical matrix device with a two-dimensional matrix arrangement of elements relating to light and having active elements and capacitors formed of thin-film transistors (TFTs) or the like is in wide use today. The element relating to light includes a light receiving element and a display element. This optical matrix device is roughly classified as a device formed of light receiving elements and a device formed of display elements. The device formed of light receiving elements includes an optical image sensor, and a radiation image sensor for use in the medical field, industrial field or the like. The device formed of display elements includes an image display for use as a monitor of a television or a personal computer, such as a liquid crystal type having elements that adjust intensity of transmitted light and an EL type with light emitting elements. Here, light refers to infrared light, visible light, ultraviolet light, radiation (X-rays, gamma-rays), and the like.

In recent years, a method using printing technique has been studied vigorously as a method of forming wires of an active matrix substrate provided in such an optical matrix device. In particular, attention has been paid to a method using inkjet technique. Formation through inkjet technique may be made of not only gate wires and data wires of the active matrix substrate, but also a semiconductor film of such as gate channels. This is very useful, unlike the conventional photolithographic technique, in that local printing may be achieved and no masking is required. For such a reason, this is expected as technique for manufacturing an active matrix substrate with a larger area.

With the inkjet printing technique, printing and coating of droplets (ink) containing semiconductor, insulator or conductive particles may achieve formation of a semiconductor film, an insulator conducting wires. Droplets ejected from an ink jet nozzle are maintained as a solution or in a colloidal state by dissolving or dispersing any of the semiconductor, insulator or conductive particles in an organic solvent. Then, these droplets are printed and coated, and thereafter the organic solvent is volatized through a heating treatment to form a semiconductor film, an insulator film or conducting wires (wiring).

For instance, Japanese Patent No. 3541625 (“JP '625”) discloses a method of manufacturing a display device provided with top-gate thin transistors through inkjet technique.

There may arise a problem, however, that the droplets impacting the substrate always have an unstable shape, since the droplets ejected through the inkjet technique are liquid. JP '625 solves the problem by forming banks to fix a position of the ejected droplets. On the other hand, formation of the banks loses flexibility in printing and drawing, which may be counterproductive.

This invention has been made regarding the state of the art noted above, and its object is to provide a method of manufacturing an optical matrix device that enhances positional accuracy of printing patterns in spite of using printing technique.

### SUMMARY

This invention is constituted as stated below to achieve the above object. An example of the invention is a method of manufacturing an optical matrix device having thin film transistors arranged on a substrate two-dimensionally in a matrix array by printing technique. The method includes an extension-promoting pattern formation step of forming an extension-promoting pattern that promotes extension of droplets to be applied through forming a pattern of projections and depressions or a pattern of parallel lyophobic portions and lyophilic portions as to be parallel to the printing pattern formed on a foundation layer where printing patterns are to be formed as an electric conductor of the optical matrix device, and an extension-inhibiting pattern formation step of forming an extension-inhibiting pattern that inhibits extension of the droplets at ends of the printing patterns on the foundation layer through forming a pattern of projections and depressions or a pattern of parallel lyophobic portions and lyophilic portions as to intersect the printing pattern, the printing patterns that intersect each other being formed through intersecting the extension-promoting patterns in each printing pattern on the foundation layer or through intersecting partially the extension-promoting pattern in the first printing pattern and the divided extension-promotion pattern in the second printing pattern.

According to the method of manufacturing the optical matrix device in this example of the invention, the extension-promoting formation step may achieve formation, on the foundation layer having the printing patterns formed therein, of the extension-promoting pattern for promoting extension of the droplets to be applied. In addition, the extension-inhibiting formation step may achieve formation of the extension-inhibiting pattern for inhibiting extension of the droplets to be applied. Consequently, the droplets applied on the foundation layer extend along the extension-promoting pattern and stop extension by the extension-inhibiting pattern. Thus, although the droplets are liquid, a coating position thereof may be controlled accurately. In addition, the droplets may be prevented from flowing sideways and excessively extending. Accordingly, the printing patterns may be formed with enhanced positional accuracy,

Moreover, where the printing patterns intersecting each other are formed, the extension-promoting puke in each printing pattern intersect on the foundation layer. Accordingly, the printing patterns may each be prevented from contacting while extension of the droplets in each printing pattern may be promoted. Alternatively, the extension-promoting pattern in a first printing pattern and the extension-promotion pattern in a second printing pattern may intersect partially.

As noted above, where the printing patterns intersecting each other are formed, the extension-promoting patterns intersect completely or partially. The printing pattern intersecting each other may be formed accurately through execution of a first printing pattern formation step, a second printing pattern formation step, an insulation film on intersection formation step, and a third printing pattern formation step. The first printing formation step is executed for forming a first printing pattern along the extension-promoting pattern. The second printing pattern formation step is executed for forming a second printing pattern divided at an intersect of each printing pattern. The insulation film on intersection formation step is executed for forming an insulation film on the first printing pattern formed at the intersection. The third printing pattern formation step is executed for forming a third printing pattern on the insulation film formed at the intersection, whereby the second printing pattern divided at the intersection is connected.

Moreover, the extension-promoting pattern may be formed through forming a pattern of projections and depressions parallel to the printing pattern formed on the foundation layer. The extension-inhibiting pattern may be formed through forming a pattern of projections and depressions as to intersect the printing pattern formed on the foundation layer.

The extension-promoting pattern may also be formed by a method, other than that of the forming pattern of projections and depressions, of forming a pattern of parallel lyophobic portions and lyophilic portions on the printing pattern on the foundation layer. Moreover, the extension-inhibiting pattern may be also formed by a method, other than that of forming the pattern of projections and depressions, of forming a pattern having parallel lyophobic portions and lyophilic portions as to intersect the printing pattern.

Moreover, the printing pattern includes gate lines, data lines, ground lines, or capacitive electrodes. These may be formed having enhanced positional accuracy through printing technique. The printing pattern also includes electrodes of the thin film transistor that may be formed with enhanced positional accuracy through printing technique.

Moreover, imprinting technique is used for formation of the extension-promoting pattern or the extension-inhibiting pattern. Accordingly, the extension-promoting pattern or the extension-inhibiting pattern may be formed accurately. Moreover, inkjet technique is used for formation of the printing pattern. Accordingly, the printing pattern may be formed on demand, which results in increased flexibility in drawing of the printing pattern. Consequently, various types of optical matrix devices of smaller lots may also be formed efficiency.

The printing pattern with enhanced positional accuracy is formed through the method of manufacturing the optical matrix device mentioned above. Consequently, a light detector, a radiation detector, or an image display device may be manufactured with smaller property variations among lots.

With the optical matrix device according to this invention, a method of manufacturing an optical matrix device may be provided that enhances positional accuracy of a printing pattern in spite of using printing technique.

### BRIEF DESCRIPTION OF THE DRAWINGS

FIG. 1 is a flow chart showing a flow of manufacturing a flat panel X-ray detector (FPD) according to an example.

FIGS. 2 and 3 are vertical sectional views each showing process of manufacturing the FPD according to the example.

FIG. 4 is a schematic perspective view showing the process of manufacturing the FPD according to the example.

FIG. 5 is a vertical sectional view showing the process of manufacturing the FPD according to the example.

FIGS. 6 and 7 are front views each showing the process of manufacturing the FPD according to the example.

FIG. 8 is a schematic perspective view showing the process of manufacturing the FPD according to the example.

FIGS. 9 through 16 are front views each showing the process of manufacturing the FPD according to the example.

FIGS. 17 and 18 are vertical sectional views each showing the process of manufacturing the FPD according to the example.

FIG. 19 is a front view showing the process of manufacturing the FPD according to the example.

FIG. 20 is a vertical sectional view showing the process of manufacturing the FPD according to the example.

FIG. 21 is a front view showing the process of manufacturing the FPD according to the example.

FIGS. 22 through 25 are vertical sectional views each showing the process of manufacturing the FPD according to the example.

FIG. 26 is a circuit diagram showing a configuration of an active matrix substrate and adjacent circuits provided for the FPD according to the example.

FIG. 27 is a front view showing process of manufacturing an FPD according to another example.

FIG. 28 is a vertical sectional view showing the process of manufacturing the FPD according to the other example.

FIG. 29 is a schematic perspective view showing an image display device having an active matrix substrate prepared through a method according to a further example.

FIGS. 30 through 32 are front views each showing process of manufacturing FPD according to an example of the present invention.

### DETAILED DESCRIPTION

Flat Panel X-ray Detector Manufacturing Method

Description will be given hereinafter of a method of manufacturing a flat panel X-ray detector (hereinafter, referred to as FPD) as one example of an optical matrix device according to this invention with reference to the drawings.

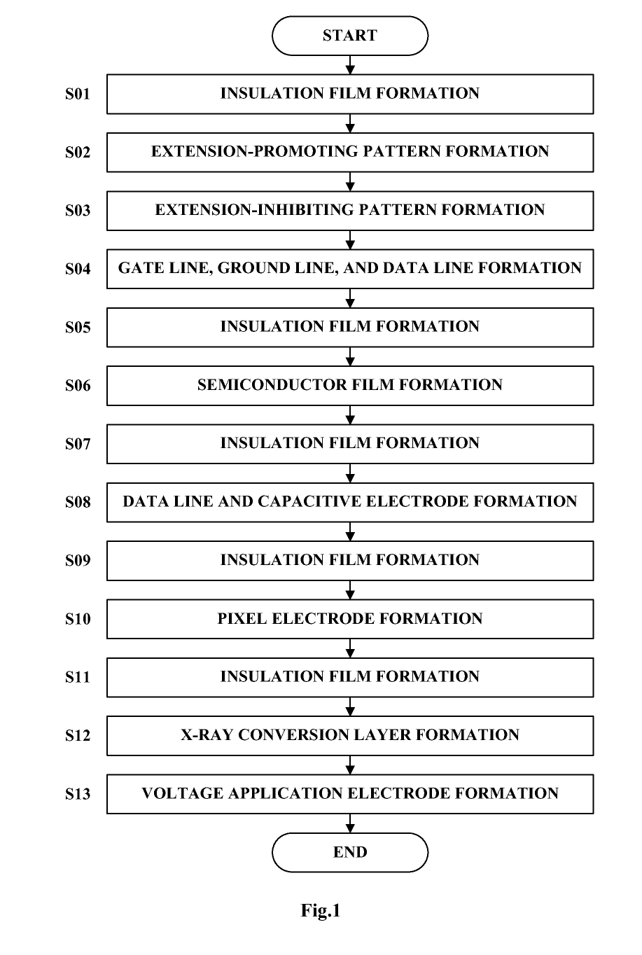

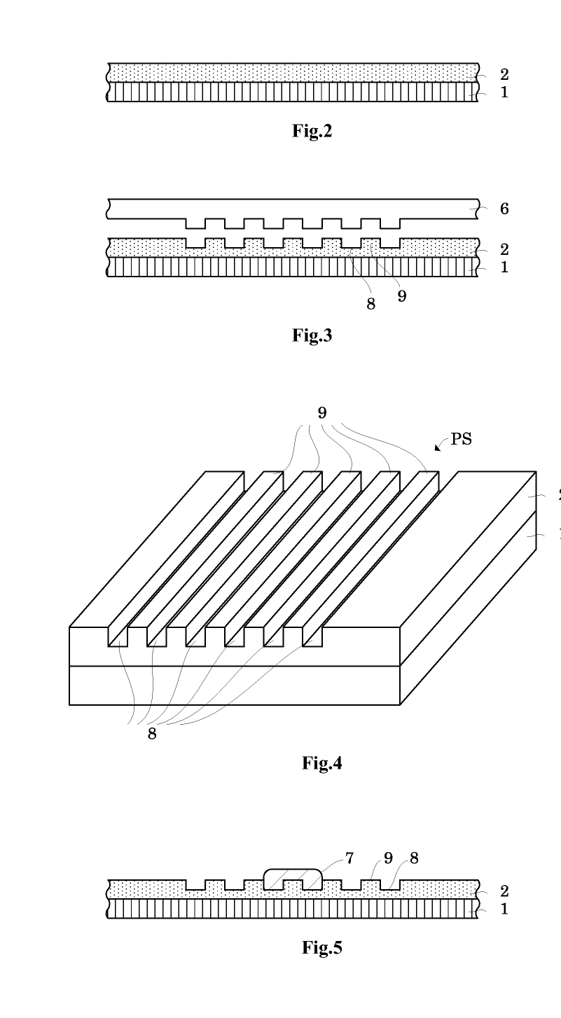

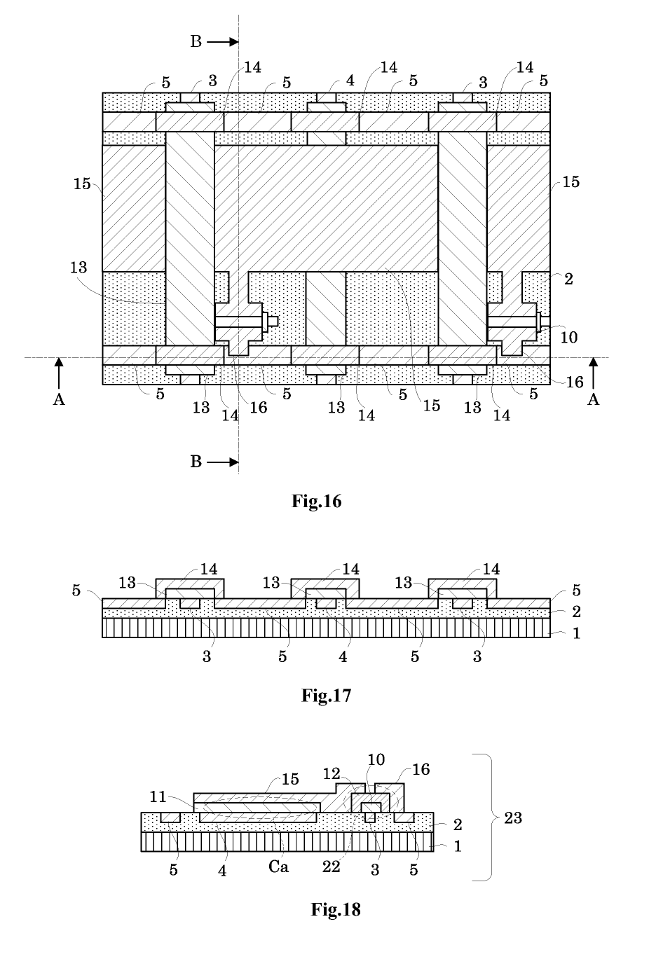

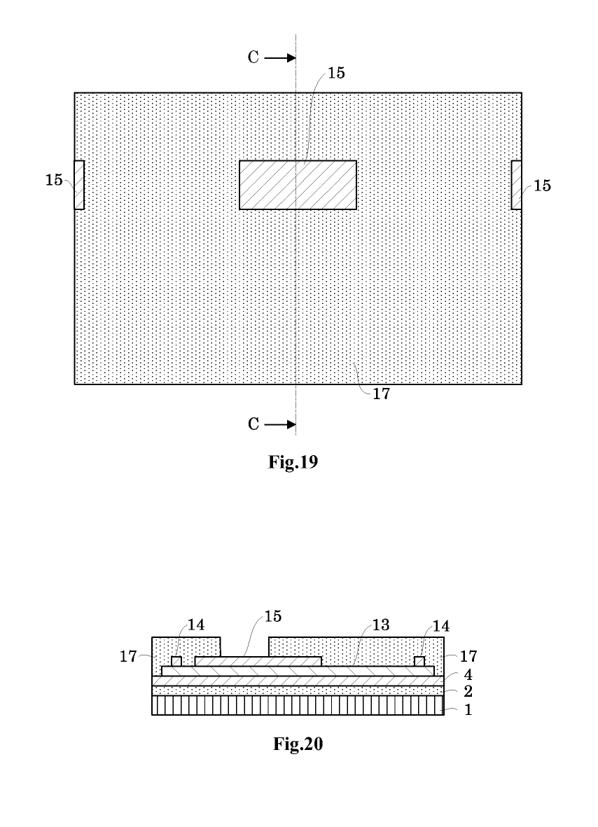

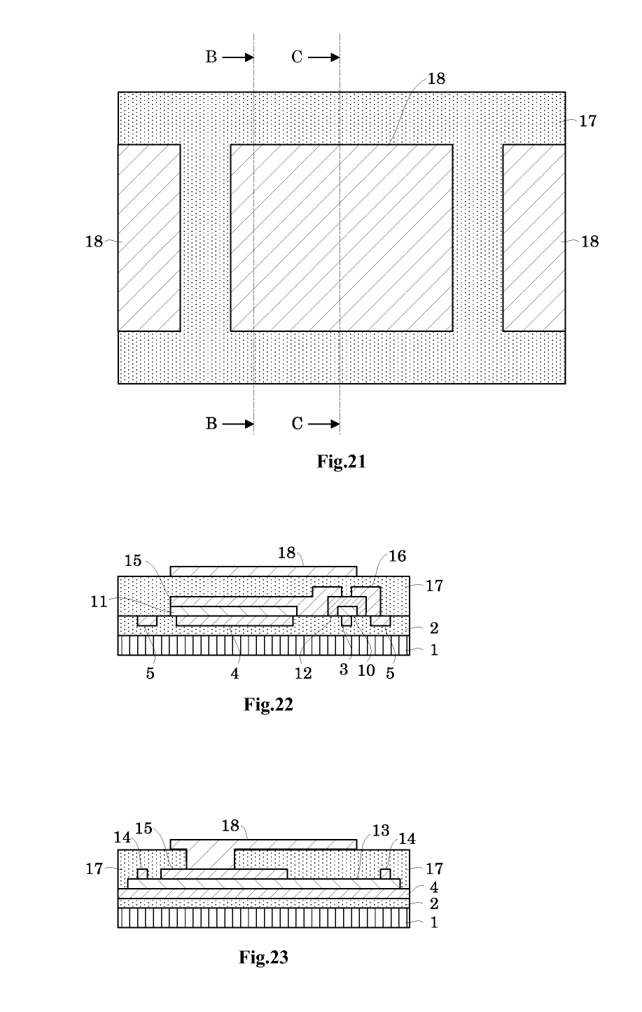

FIG. 1 is a flow chart showing a flow of process of manufacturing an FPD according to an example. FIGS. 2 through 26 are views each showing the process of manufacturing the FPD according to the example. FIG. 17 is a section taken on line A-A of FIG. 16. FIG. 18 is a section taken on line B-B of FIG. 16. FIG. 20 is a section taken on line C-C of FIG. 19. FIG. 22 is a section taken on line B-B of FIG. 21, FIG. 23 is a section taken on line C-C of FIG. 21.

(Step S01) Insulation Film Formation

As shown in FIG. 2, an insulation film 2 is formed uniformly on a surface of a substrate 1. The substrate lay be any one of glass, a synthetic resin and a metal. Examples of the synthetic resin include polyimide, PEN (polyethylene naphthalate), PES (polyether sulfone), PET (polyethylene terephthalate), PC (polycarbonate), PMMA (poly methyl methacrylate), PDMS (the poly dimethyl siloxane), and the like. Polyimide is preferable that is excellent in heat resistance.

It is preferable that the insulation film 2 is formed of an organic material, and is thermoplastic or is cured with light. Such material includes polyimide, an acrylic resin, and a UV cured resin. Where the substrate 1 and the insulation films 2 are formed of an organic material such as a synthetic resin, a flexible substrate may be manufactured. Accordingly, there arises an advantage that the substrate is not broken even if it drops. Moreover, where the insulation film 2 is formed of an organic material, coating may be performed with ease at room temperatures. The insulation film 2 corresponds to the foundation layer in this invention.

(Step S02) Extension-Promoting Pattern Formation

As shown in FIGS. 3 and 4, the insulation 2 formed on the substrate 1 is maintained in a soften state. A pattern of projections and depressions having depressions 8 and projections 9 arranged parallel to the printing pattern is formed alternatively and parallel on the insulation film 2 where the printing patterns of gate lines 3, ground lines 4, and data lines 5 are to be formed in subsequent processes. The pattern of projections and depressions is formed on the insulation film 2 having a larger width than the printing pattern. As above, the pattern of projections and depressions is formed as to be parallel to the printing pattern on the insulation film 2 where the printing pattern is formed, which results in formation of the extension-promoting pattern PS. Here, imprinting technique that a transfer mold 6 having the pattern of projections and depressions formed in advance is pressed against the insulation film 2 is preferable for the depression-projection pattern formation method. Where the insulation film 2 is thermoplastic, thermal imprinting technique is adopted that the insulation film 2 is heated in advance to be maintained in a soften state and the transfer mold 6 is pressed against the insulation film 2. The pattern of the transfer mold 6 is transferred on the insulation film 2, and then the insulation film 2 is cooled for cure. Thereafter, the transfer mold 6 is removed from the insulation film 2. Accordingly, as shown in FIGS. 3 and 4, the extension-promoting pattern PS for grooves of the projections and depressions is formed on the insulation film 2 as a foundation of the printing pattern to be formed in the subsequent processes.

Where the insulation film 2 is of ultraviolet curable type, the transfer mold 6 is pressed against the insulation film 2 in a softened state to form the pattern of projections and depressions on the insulation film 2. Thereafter, the insulation film 2 is irradiated with ultraviolet rays. Such irradiation with ultraviolet rays may cure the insulation film 2 to fix the pattern of projections and depressions thereon. The transfer mold 6 may be formed with Si (silicon), Ni (nickel), PDMS, etc. The pattern of the transfer mold 6 may be formed through EB exposure or photolithography. Alternatively, the pattern of projections and depressions may be formed on the insulation film 2 through soft lithography (micro contacting technique.) Here, Step S02 corresponds to the extension-promoting pattern formation step in this invention.

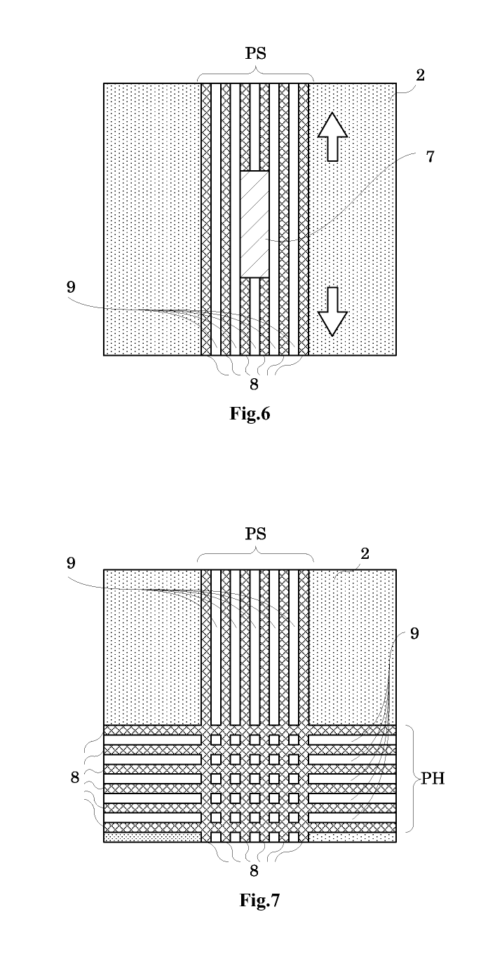

When the droplets 7 are printed and coated on the extension-promoting pattern PS, the droplets 7 extend while being introduced along the depressions 8 of the extension-promoting pattern PS, as shown in FIGS. 5 and 6. Specifically, the droplets 7 may extend along the depressions 8 in a direction parallel to the extension-promoting pattern PS. On the other hand, in a direction intersecting the extension-promoting pattern PS, the droplets 7 tend to extend along the depressions 8 rather than in a direction extending over to intersect the projections 9. That is because the insulation film 2 has an uneven shape in a printed and coated portion thereof. In this way, the droplets 7 extend along the extension-promoting pattern PS. Here, the depression 8 and projection 9 preferably have a width of 100 nm or more, and of half or less the diameter of the droplets 7 to be printed and coated. Moreover, difference in level between the depression 8 and the projection 9 is preferably from 10 nm o ore to 10 μm or less.

(Step S03) Extension-Inhibiting Pattern Formation

The extension-inhibiting pattern PH for inhibiting extension of the droplets 7 to be printed and coated is formed at ends where the printing pattern on the insulation film 2 having extension-promoting pattern PS is to be formed. As shown in FIG. 7, the pattern of projections and depressions is formed so as to intersect the printing pattern, i.e., the extension-promoting pattern PS. The pattern of projections and depressions is formed by the same method as the extension-promoting pattern PS, and thus description thereof is to be omitted. Formation of the extension-inhibiting pattern PH may inhibit extension of the droplets 7 along the extension-promoting pattern PS. Step S3 corresponds to the extension-inhibiting pattern formation step in this invention.

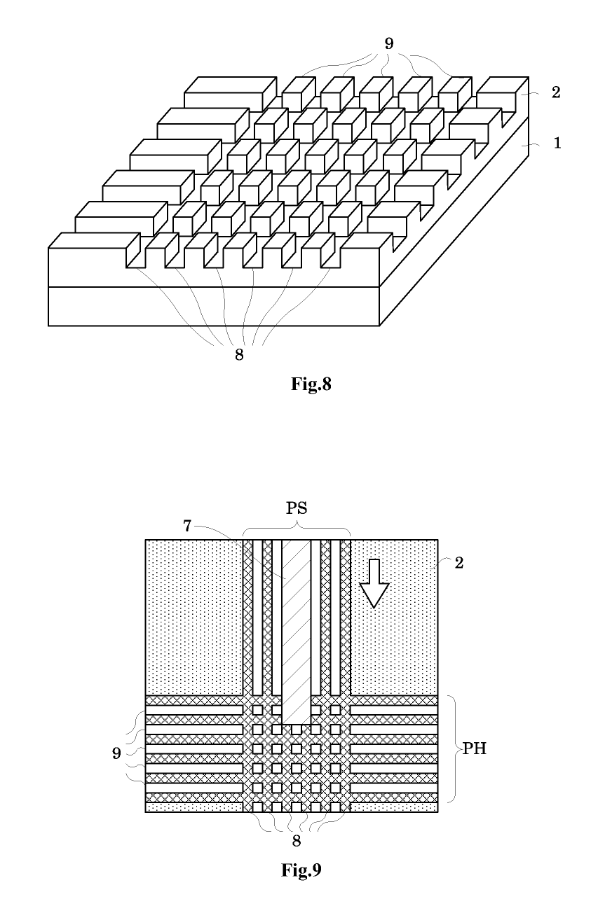

As shown in FIG. 8, the pattern of projections and depressions intersects each other at an intersection of the extension-promoting pattern PS and the extension-inhibiting pattern PH, whereby cubical or rectangular parallelepiped projections are formed. Accordingly, as shown in FIG. 9, the cubical or rectangular parallelepiped projections inhibit and stop extension of the droplets 7 along the extension-promoting pattern PS.

(Step S04) Gate Line, Ground Line, and Data Line Formation

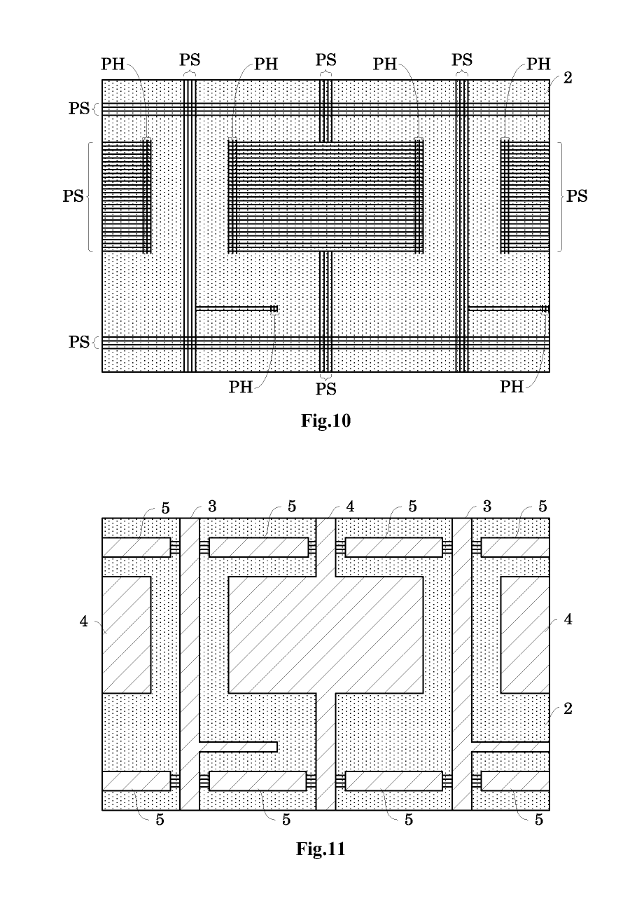

As shown in FIG. 10, the extension-promoting pattern PS of projections and depressions is formed through Step S02 on the insulation film 2 at a position of the pattern where the gate lines, the ground lines, and the data lines are printed. In addition, the extension-inhibiting pattern PH is formed at end portions of each wiring pattern through Step S03. When the printing patterns such as the gate and data lines intersect each other, each extension-promoting pattern PS may intersect.

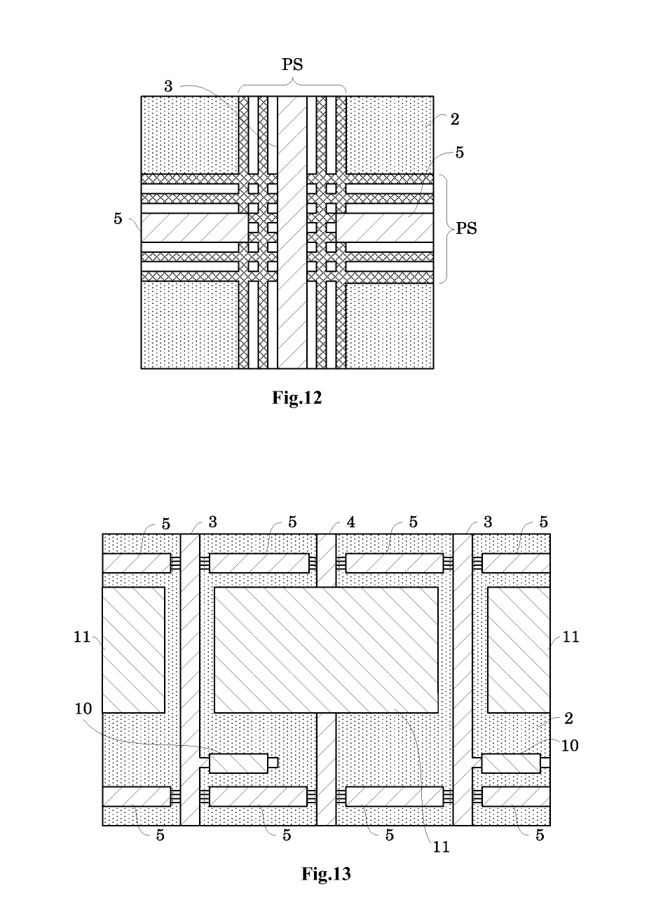

As shown in FIG. 11, metal ink is coated, using printing technique, on the insulation film 2 having the extension-promoting pattern PS and the extension-inhibiting pattern PH formed thereon. Thus, the gate lines 3, the ground lines 4, and the data lines 5 are formed. Here, the gate lines and data lines intersect each other. Accordingly, only the gate lines 3 are formed in advance, and then the data lines are formed as data lines 5 to be divided around the intersection. At the intersection shown in FIG. 12, the extension-promoting pattern PS of the gate lines 3 serves as the extension-inhibiting pattern PH for the extension-promoting pattern PS of the data lines 5, which results in prevention of contacting the printing pattern of the data lines 5 to the printing pattern of the gate lines 3. Moreover, extension of the printing pattern of the gate lines 3 is inhibited at the intersection of the gate lines 3 and the data lines 5. Accordingly, smaller printing pitches of the date lines 3 are needed. Herein, Step S04 corresponds to the first printing pattern formation step and the second printing pattern formation step in this invention.

(Step S05) Insulation Film Formation

As shown in FIG. 13, a gate insulation film 10 is formed at a given position on the gate lines 3, and an insulation film 11 is formed on a portion of the ground line 4.

(Step S06) Semiconductor Film Formation

As shown in FIG. 14, a semiconductor film 12 is formed on the gate insulation film 10 on the gate line 3. The formation method thereof includes printing technique, spattering process, micro contacting technique, etc. The semiconductor film 12 acts as a gate channel.

(Step S07) insulation Film Formation

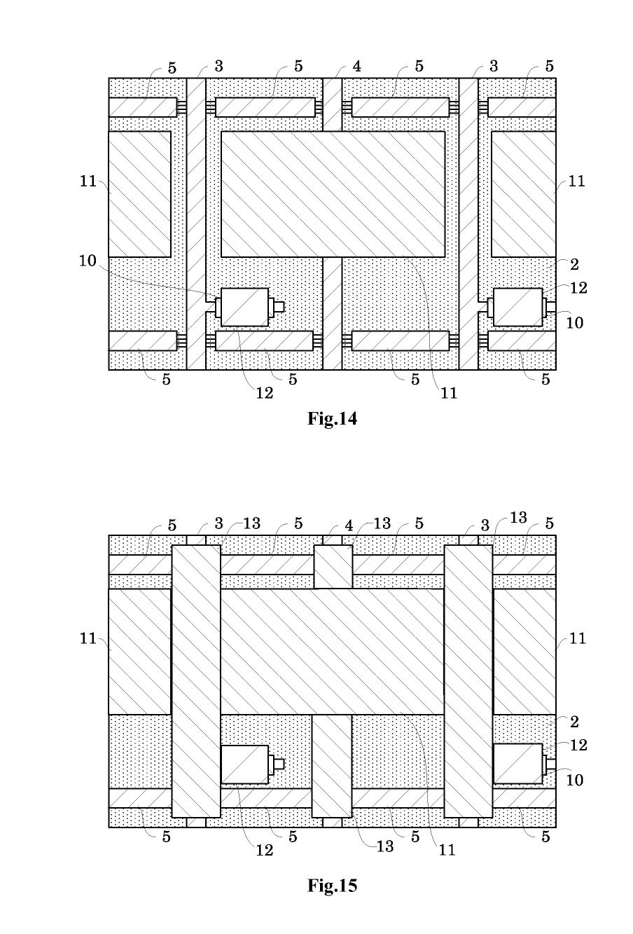

Next, as shown in FIG. 15, an insulation film 13 is formed on a portion of the gate line 3, the ground line 4, and. the data line 5. Accordingly, the insulation film is formed on the gate line 3 at the intersection of the gate line and the data line. Step S07 corresponds to the insulation film at intersection formation step in this invention.

(Step S08) Data Line and Capacitive Electrode Formation

Next, as shown in FIG. 16 and FIG. 17 as a section taken on line A-A thereof, a data line 14 is formed on an insulation film 13 as to connect the divided data lines 5. Each end portion of the data lines 14 is connected to the divided data line 5. Accordingly, one wiring having the data lines 5 and 14 being electrically connected is formed. Moreover, as shown in FIG. 18 as a section taken on line B-B of FIG. 16, capacitive electrode 15 is laminated across the insulation film 11 as to be directed toward the ground line 4. In this way, the capacitor Ca is formed with the ground line 4, the capacitive electrode 15, and the insulation film 11 therebetween. The capacitive electrode 15 is also formed on a portion of the semiconductor film 12 as a gate channel. Accordingly, a portion of the electrode 15 on the semiconductor film 12 acts as a source electrode. Moreover, a data line 16 that connects the semiconductor film 12 and the data line 5 is also formed by printing technique. Accordingly, the data line 16 acts as a drain electrode. Here, TFT 22 is formed with a portion of the date line 3 directed toward the semiconductor film 12, the data line 16, the semiconductor film 12, a portion of the capacitive electrode 15 on a semiconductor film 12 side, and the gate insulation film 10 between the gate line 3 and the semiconductor film 12. Consequently, an active matrix substrate 23 is configured having the substrate 1, the capacitive electrode 15, the capacitor Ca, the TFT 22, the semiconductor film 12, the data lines 5, 14, 16, the gate line 3, the ground line 4, the insulation film 2, the gate insulation film 10, and the insulation film 11. Step S08 corresponds to the third printing-pattern formation step in this invention.

(Step S09) Insulation Film Formation

As shown in FIG. 19 and FIG. 20 as a section taken on line C-C thereof, an insulation film 17 is laminated on the gate line 3, the ground line 4, the data lines 5, 14, 16, the capacitive electrode 15, the semiconductor film 12, the gate insulation film 10, the gate insulation film 13 and the insulation film 2. The capacitive electrode 15 is covered with the insulation film 17 other than a portion as a via-hole on the capacitive electrode 15 where the insulation film 17 is not laminated for connection with a pixel electrode 18 to be laminated. The insulation film 17 also acts as a passivation film of the TFT 22.

(Step S10) Pixel Electrode Formation

A pixel electrode 18 is laminated on the capacitive electrode 15 and the insulation film 17, as shown in FIG. 21, FIG. 22 as a section taken on line B-B of FIG. 21 as well as FIG. 23 as a section taken on line C-C of FIG. 21. Accordingly, the pixel electrode 18 is electrically connected with the capacitive electrode 15.

(Step S11) Insulation Film Formation

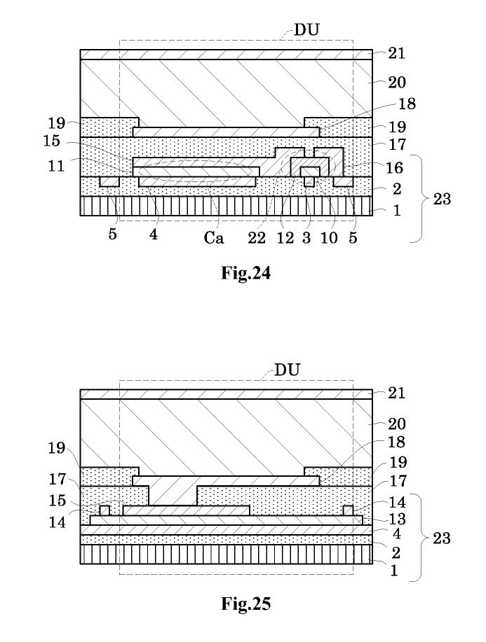

As shown in FIGS. 24 and 25, an insulation film 19 is laminated on the pixel electrode 18 and the insulation film 17. The insulation film 19 is not laminated on the major portion of the pixel electrode 18 but laminated on the periphery of the pixel electrode 18 so as to directly contact an X-ray conversion layer 20 for collecting carriers into the pixel electrode 18 that are generated with the X-ray conversion layer 20 to be laminated. That is, the insulation film 19 is laminated such that the major portion of the pixel electrode 18 is exposed.

(Step S12) X-ray Conversion layer Formation

Next, the X-ray conversion layer 20 is laminated on the pixel electrode 18 and the insulation film 19. In Embodiment 1, vapor deposition is adopted since amorphous selenium (a-Se) is laminated as the X-ray conversion layer 20 that is a light receiving element. The laminating method may be changed according to the type of semiconductor used for the X-ray conversion layer 20.

(Step S13) Voltage Application Electrode Formation

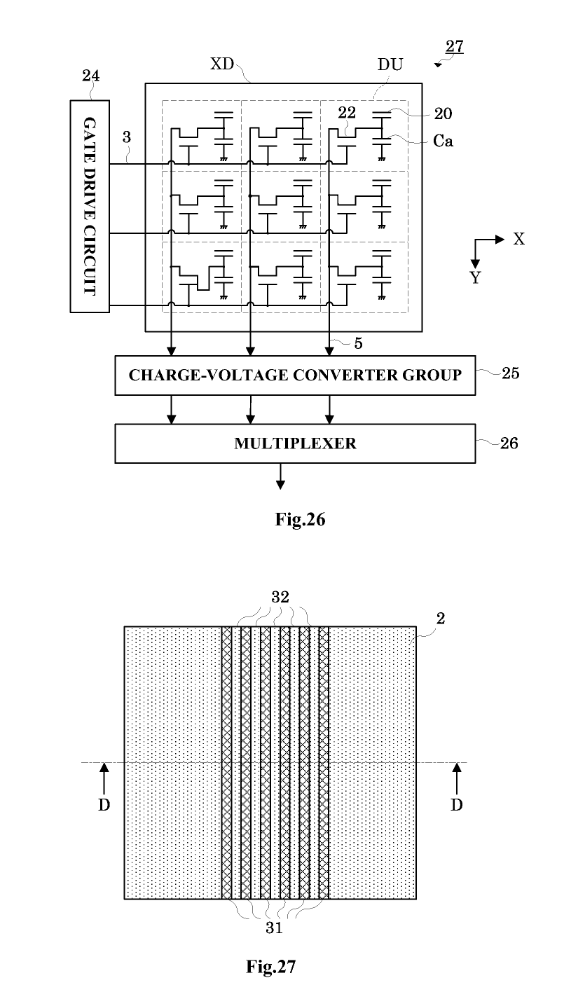

Next, a voltage application electrode 21 is laminated, on the X-ray conversion layer 20. Subsequently, as shown in FIG. 26, peripheral circuits such as a gate drive circuit 24, a charge-voltage converter group 25 and, a multiplexer 26 are connected to complete a manufacturing series of the FPD 27.

The insulation film 2, 11, 13, 17,19 and the gate insulation film 10 of the FPD 27 are preferably formed partially by inkjet technique, and are preferably formed uniformly on the substrate by spin coat technique. Alternatively, they may be formed otherwise, such as by letterpress printing technique, photogravure technique, flexography, and roll-to-roll process.

The method of forming the extension-promoting pattern PS and the extension-inhibiting pattern PH may he performed collectively throughout the insulation film 2, or may be performed repeatedly to smaller divided regions. Alternatively, the extension-promoting pattern PS and the extension-inhibiting pattern PH may each be formed on the insulation films 11 and 13 prior to formation of the capacitive electrode 15 and the data line 14.

Flat Panel X-Ray Detector

As shown in FIG. 26, the FPD 27 manufactured as described above includes an X-ray detector XD for receiving X-rays having X-ray detecting elements DU arranged in XY directions in a two-dimensional matrix. The X-ray detecting elements DU are operable in response to incident X-rays, and output charge signals for every pixel. For convenience of description, FIG. 26 shows the X-ray detecting elements DU in a two-dimensional matrix arrangement for 3×3 pixels. In the actual X-ray detector XD, the X-ray detecting elements DU are in a matrix arrangement for 4096×4096 pixels, for example, to match the number of pixels of the FPD 27. The X-ray detecting element DU corresponds to the element relating to light in this invention.

As shown in FIGS. 24 and 25, the X-ray detecting elements DU have, formed under the voltage application electrode 21 to which a bias voltage is applied, the X-ray conversion layer 20 that generates carriers (electron-hole pairs) in response to incident X-rays. The pixel electrodes 18 are formed under the X-ray conversion layer 20 for collecting the carriers for every pixel. Further, an active matrix substrate 23 is formed having the capacitors Ca for storing electric charges generated by the carriers collected by the pixel electrodes 18, the TFT 22 electrically connected to the capacitors Ca, the gate lines 3 for sending signals of switching action to the TFT 22, the data lines 5 for reading the electric charges from the capacitors Ca through the TFT 22 as X-ray detection signals, and the substrate 1 for supporting these. With the active matrix substrate 23, X-ray detection signals may be read out for every pixel from the carriers generated in the X-ray conversion layer 20. In this way, each X-ray detecting clement DU includes the X-ray conversion layer 20, the pixel electrode 18, the capacitor Ca, and the TFT 22.

The X-ray conversion layer 20 is formed of an X-ray sensitive semiconductor, and is formed of non-crystalline, amorphous selenium (a-Se) film, for example. It has a construction (direct conversion type) that directly generates a given number of carriers proportional to the energy of the X-rays upon entering of X-rays into the X-ray conversion layer 20. In particular, the a-Se film may easily provide an enlarged detection area. The X-ray conversion layer 20 may be a polycrystalline semiconductor film, other than the above, such as Cd Te (cadmium telluride).

Thus, the FPD 27 in this embodiment is a flat panel X-ray sensor of two-dimensional array with the numerous X-ray detecting elements DU as X-ray detection pixels arranged along the XV directions. Each X-ray detecting element DU may perform local X-ray detection, which allows a two-dimensional distribution measurement of X-ray intensity.

The FPD 27 in this embodiment detects X-rays as follows. That is, when X-rays are emitted to a subject to perform X-ray imaging, a radiological image transmitted through the subject is projected to the X-ray conversion layer, and carriers proportional to density variations of the image are generated within the a-Se film. The generated carriers are collected into the pixel electrodes 18 due to an electric field produced by the bias voltage. Electric charges corresponding to the number of carriers generated are induced by and stored in the capacitors Ca. Subsequently, a gate voltage sent through the gate lines 3 from the gate drive circuit 24 causes the TFT 22 to take switching action. The charges stored in the capacitors Ca are outputted via the TFT 22 and through the data lines 5 to be converted into voltage signals by the electric charge-voltage converter group 25. and read out in order as X-ray detection signals by the multiplexer 26.

An electric conductor such as the data lines 5, 14, 16, the gate lines 3, the ground lines 4, the pixel electrodes 18, the capacitive electrodes 15 and the voltage application electrode 21 in the above FPD 27 may be formed by printing with metal ink produced by making a metal such as Ag (silver), Au (gold), Cu (copper) or the like into paste form. An organic ink of high conductivity represented by polyethylene dioxythiophene doped with polystyrene sulfonate (PEDOT/PSS), or ITO ink may be printed to form an electric conductor. Alternatively, an electric conductor may be configured with ITO and an Au thin film. An electric conductor is preferably formed partially by inkjet technique in printing technique. Alternatively, an electric conductor may be formed by letterpress printing technique, photogravure technique, flexography, and roll-to-roll process.

In the foregoing Embodiment 1, the X-ray conversion layer 22 generates carriers in response to X-rays, but X-rays are not limitative. it is also possible to use a radiation conversion layer sensitive to radiation such as gamma rays, or a light conversion layer sensitive to light. A photodiode may also be used instead of the light conversion layer. Accordingly, a radiation detector and a photo-detector having a similar structure may be manufactured.

According to the method of manufacturing the optical matrix device as noted above, when the wires, the semiconductor film, and the insulation film forming the active matrix substrate 23 in the FPD 27 are formed through printing and coating, the extension-promoting pattern PS is formed parallel to the printing pattern or insulation film having the printing pattern for promoting extension of the droplets 7 to be printed, and the extension-inhibiting pattern PH is formed at each end portion of the printing pattern for inhibiting extension of the droplets 7 to be printed. Consequently, positional accuracy of the droplets 7 that easily flow sideways may be enhanced, which allows in accurate formation of the printing pattern.

Moreover, the pattern of projections and depressions of the extension-promoting pattern PS and the extension-inhibiting pattern PH is formed through imprint technique, which allows in formation of the depression-projection pattern with high positional accuracy. The pattern of projections and depressions may achieve formation of each wire and electrode with use of printing technique, especially inkjet technique. That is, the droplets 7 ejected by inkjet technique extend along the pattern of projections and depressions formed on the insulation film. Thus, the printing pattern with a uniform width and positional accuracy even through inkjet technique. Accordingly, each X-ray detecting element in the FPD 27 has a uniform size and thus results in reduction in variations of electrical performance of the radiation detector due to each production lot.

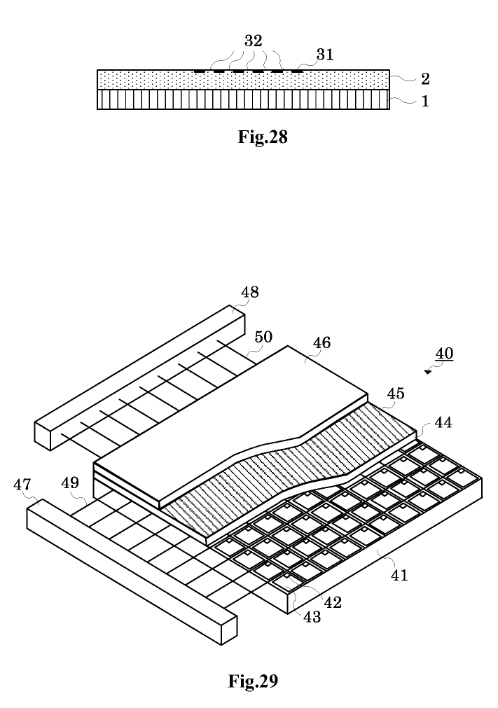

Next, another example of this invention will be described in detail hereinafter with reference to the drawings. FIG. 27 is a front view showing an extension-promoting pattern on an insulation film 2. FIG. 28 is a section taken on line D-D of FIG. 27. Elements similar to those above are denoted as the same reference numbers, and description thereof is to be omitted.

The difference between the examples is that the pattern of projections and depressions is formed on the insulation film 2 as a foundation layer, whereby the extension-promoting pattern PS and the extension-inhibiting pattern PH are formed. On the other hand, in a separate example, an alternate pattern of portions that are lyophilic and lyophobic to the droplets 7 printed and coated onto the foundation layer is formed, whereby an extension-promoting pattern and an extension-inhibiting pattern are formed. In other words, the depression 8 in one example corresponds to a lyophilic portion 32 in the other example. Further, the projection 9 corresponds to a lyophobic portion 31as between the two examples. The detailed description thereof is to be given as under.

In the method of forming the extension-promoting pattern, the lyophilic insulation film lyopholic to the droplets 7 to be printed and coated is adopted for the insulation film 2 as the foundation layer. Alternatively, the insulation film 2 is lyophilized. Then the lyophobic portions 31 lyophobic to the droplets 7 are formed on the lyophilic insulation film 2. Accordingly, the pattern having the lyophilic portions 32 lyophilic to the droplets 7 and the lyophobic portions 31 lyophobic to the droplets 7 arranged alternatively may be formed appropriately parallel to the printed and coated pattern.

Description will be given of a method of forming the lyophobic portion 31. First, a resist layer is laminated on the insulation film 2. Next, imprint technique is performed onto the resist layer to form projections and depressions. Then the depressions are etched to form a mask. Then plasma treatment is performed in a fluorine atmosphere (CF4, SF6 or the like) for the mask, which lyphobizes surfaces of the resist film and the insulation film 2. Then a developing process is performed for removal of the resist film as the mask, whereby the pattern may be formed on the insulation film 2 having the lyophilic portions 32 and the lyophobic portions 31 arranged alternatively and parallel to each other.

Moreover, the extension-inhibiting pattern may be formed by the method mentioned above such that the alternative parallel pattern of the lyophobic portions 31 and the lyophilic portions 32 intersects the printing pattern. That is, the extension-inhibiting pattern may be formed as to intersect the extension-promoting pattern.

As noted above, the alternative parallel patterns of lyophobic portions 31 and the lyophilic portions 32 are formed parallel to the printing pattern or intersect the printing pattern on the insulation film 2 on a position where the printing pattern is formed, whereby the extension-promoting pattern or the extension-inhibiting pattern is formed. Consequently, positional accuracy of the wires, the insulation film, and the semiconductor film that are printed and coated may be enhanced.

Next, a further example of this invention is described with reference to FIG. 29. FIG. 29 is a partly cutaway perspective view of a display (organic EL display) having an active matrix substrate, as an example of image display devices.

The method of this example is preferably applied also to manufacture of image display devices. Examples of the image display devices include a thin electro-luminate display and a liquid crystal display. An image display device also has pixel circuits formed in the active matrix substrate, and application to such a device is desirable.

As shown in FIG. 29, an organic EL display 40 haying an active matrix substrate includes a substrate 41, an organic EL layer 44, a transparent electrode 45 and a protective film 46 successively laminated on the substrate 41 and connected to TFT circuits 42 and pixel electrodes 43 arranged in a matrix form on the substrate 41, source electrode lines 49 connecting each TFT circuit 42 and a source drive circuit 47, and gate electrode lines 50 connecting each TFT circuit 42 and a gate drive circuit 48. Here, the organic EL layer 44 is formed by laminating respective layers such as an electron transport layer, a luminous layer and a hole transport layer.

In the organic EL display 40, the extension-promoting pattern and the extension-inhibiting pattern are formed on the insulation film where the source electrode lines 49 and the gate electrode lines 50 are printed and coated through the method of manufacturing the optical matrix device in the above examples. Consequently, positional accuracy of the printing pattern may be enhanced. Accordingly, property variations among production lots may be suppressed.

The above image display device uses display elements such as organic EL, but is not limited to this. That is, it may be a liquid crystal display having liquid crystal display elements. With the liquid crystal display, pixels are colored RGB by color filters. Moreover, use of transparent wires and a transparent substrate may bring an advantage of enhancing transmission efficiency of light. It may also be a display having other display elements.

This invention is not limited to the foregoing embodiment, but may be modified as follows:

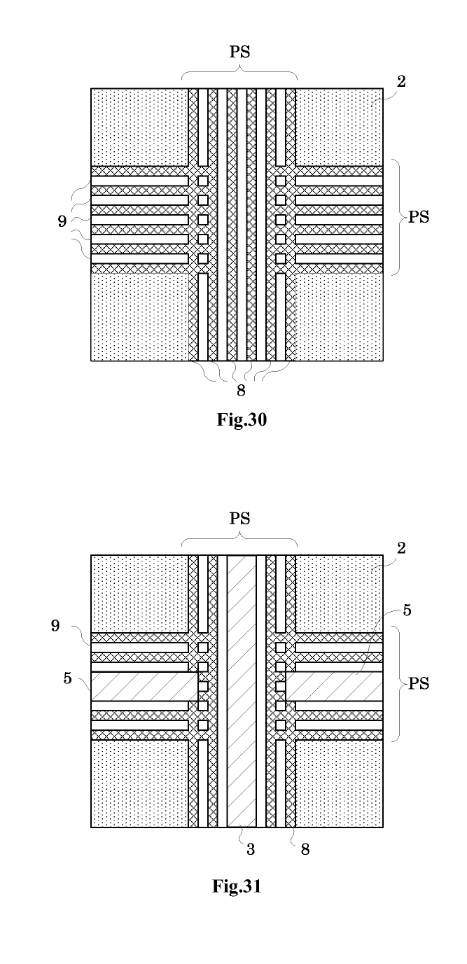

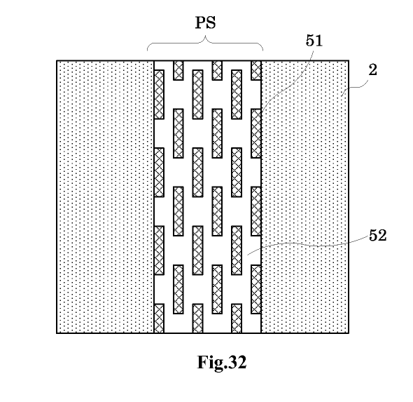

(1) In the foregoing embodiments, the printing pattern of the gate lines 3 intersects the printing pattern of the data lines 5, 14. Accordingly, the extension-promoting patterns of the gate lines 3 and the data lines 5 intersect each other. Alternatively, as shown in FIG. 30, a portion of the first extension-promoting pattern intersects the second extension-promoting pattern. Accordingly, the extension-promoting pattern of the data lines 5 does not prevent the droplets 7 forming the gate line 3 from extending. Consequently, as shown in FIG. 31, smaller printing pitches are not needed at the intersection of the extension-promoting pattern in printing and coating of the gate lines 3, which results in efficient printing formation.

(2) In the foregoing embodiments, the extension-prom pattern ay be consecutively linear. Alternatively, as shown in FIG. 32, they may be a pattern of inconsecutively linear projections 51 and depressions 52. The projections 51 are formed parallel to each other. The projection 51 preferably has an aspect ratio of 2:1 or more, and further preferably an aspect ratio of 5:1 or more. Extension of the droplets 7 tends to be promoted. as the depression 51 has a larger length than a width.

(3) In the foregoing embodiments, the insulation film 2 is a foundation layer. Alternatively, a foundation layer may be formed on the insulation film 2. Alternatively, a mixture of an organic film and an inorganic film may be adopted as a foundation layer. Moreover, the extension-promoting pattern and the extension-inhibiting pattern may be formed not only on the insulation film 2 but also on the insulation film 11 or 13, which achieves accurate printing of the data lines 14 and the capacitive electrodes 15. As noted above, the extension-promoting pattern PS and the extension-inhibiting pattern PH may be formed for the printing pattern not only on the lowermost layer of the active matrix substrate but also on the second and third layers.

(4) In the foregoing embodiments, the ground lines 4 are formed parallel to the gate lines 3. Alternatively, the ground lines 4 may be formed parallel to the data lines 5. Where two types of wires intersect that are selected from three types of wires, i.e., the gate lines 3, the ground lines 4, and the data lines 5, any types of wires may be formed on the lower layer of the active matrix substrate.

(5) in the foregoing examples, the droplets 7 are metal ink such as Ag and Au. Alternatively, the droplets 7 may be applied in formation of the insulation film with use of polyimide ink. In other words, the insulation film may be formed on the foundation layer having enhanced positional accuracy through printing technique.

(6) In the foregoing embodiments, the optical matrix device includes bottom-gate TFTs. Alternatively, the optical matrix device may include top-gate TFTs.

1. A method of manufacturing an optical matrix device having thin film transistors arranged on a substrate two-dimensionally in a matrix array with use of printing technique, comprising:
an extension-promoting pattern formation step forming an extension-promoting pattern that promotes extension of droplets to be applied through forming a pattern of projections and depressions or a pattern of parallel lyophobic portions and lyophilic portions as to be parallel to the printing pattern formed on a foundation layer where printing patterns are to be formed as an electric conductor of the optical matrix device; and
an extension-inhibiting pattern formation step forming an extension-inhibiting pattern that inhibits extension of the droplets at ends of the printing patterns on the foundation layer through forming a pattern of projections and depressions or a pattern of parallel lyophobic portions and lyophilic portions as to intersect the printing pattern,
the printing patterns that intersect each other being formed through intersecting the extension-promoting patterns in each printing pattern on the foundation layer or through intersecting partially the extension-promoting pattern in the first printing pattern and the divided extension-promotion pattern in the second printing pattern.

2. (canceled)

3. (canceled)

4. The method of manufacturing an optical matrix device according to claim 1, comprising:
a first printing pattern formation step forming a first printing pattern;
a second printing pattern formation step forming a second printing pattern divided at an intersect of each printing pattern;
an insulation film on intersection formation step forming an insulation film on the first printing pattern formed at the intersection; and
a third printing pattern formation step forming a third printing pattern on the insulation film formed at the intersection, whereby the second printing pattern divided at the intersection is connected.

5. The method of manufacturing an optical matrix device according to claim 1, wherein
the extension-promoting pattern is formed through forming a pattern of projections and depressions parallel to the printing pattern formed on the foundation layer.

6. The method of manufacturing an optical matrix device according to claim 3, wherein
the extension-inhibiting pattern is formed through forming a pattern of projections and depressions as to intersect the printing pattern formed on the foundation layer.

7. The method of manufacturing an optical matrix device according to claim 1, wherein
the extension-promoting pattern is formed by forming a pattern of parallel lyophobic portions and lyophilic portions on the printing pattern on the foundation layer.

8. The method of manufacturing an optical matrix device according to claim 7, wherein
the extension-inhibiting pattern is formed by forming a pattern having parallel lyophobic portions and lyophilic portions as to intersect the printing pattern.

9. The method of manufacturing an optical matrix device according to claim 1, wherein
the printing pattern includes gate lines, data lines, ground lines, or capacitive electrodes.

10. The method of manufacturing an optical matrix device according to claim 1, wherein
the printing pattern is electrodes of the thin film transistor.

11. The method of manufacturing an optical matrix device according to claim 1, wherein
imprinting technique is used for formation of the extension-promoting pattern or the extension-inhibiting pattern.

12. The method of manufacturing an optical matrix device according to claim 1, wherein
inkjet technique is used for formation of the printing pattern.

13. The method of manufacturing an optical matrix device according to claim 1, wherein
the optical matrix device is a light detector or a radiation detector.

14. The method of manufacturing an optical matrix device according to claim 1, wherein
the optical matrix device is an image display device.
